(19) United States
(12) Patent Application Publication
(10) Pub. No.: US 2007/0207568 A1
(43) Pub. Date: Sep. 6, 2007

(54) SiP module with a single sided lid

(76) Inventors: Hem Takiar, Fremont, CA (US); Chin-Tien Chiu, Taichung City (TW); Chih Chiang Tung, Wu Chi Town (TW)

Correspondence Address: VIERRA MAGEN/SANDISK CORPORATION, 575 MARKET STREET, SUITE 2500, SAN FRANCISCO, CA, 94105, US

(21) Appl. No.: 11/365,211

(22) Filed: Mar. 1, 2006

(51) Int. Cl. H01L 21/00

(52) U.S. Cl. 438/106

(57) ABSTRACT

A single-lid flash memory card and methods of manufacturing same are disclosed. The single-sided lid flash memory card may be formed from a semiconductor package having two or more tapered, stepped or otherwise shaped edges capable of securing a single-sided lid thereon. The taper, step or other shape may be fabricated by various methods, including during the molding step or during the singulation step. A semiconductor package having shaped edges may be enclosed within an external lid to form a finished flash memory card. The lid may be applied to a single side of the semiconductor package by various processes, including over-molding, or by pre-forming the lid with interior edges to match the exterior edges of the semiconductor package, and then sliding the lid over the package to form a tight fit therebetween. The shaped edge of the semiconductor package effectively holds the lid securely on the memory card without any adhesives and prevents the lid from dislodging from the semiconductor package.

### BACKGROUND OF THE INVENTION

1. Field of the Invention

Embodiments of the present invention relate to methods of manufacturing a semiconductor package.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid base having a conductive layer etched on one or both sides. Electrical connections are formed between the die and the conductive layer(s), and the conductive layer(s) provide an electric lead structure for integration of the die into an electronic system. Once electrical connections between the die and substrate are made, the assembly is then typically encased in a molding compound to provide a protective package.

In view of the small form factor requirements, as well as the fact that flash memory cards need to be removable and not permanently attached to a printed circuit board, such cards are often built of a land grid array (LGA) package. In an LGA package, the semiconductor die are electrically connected to exposed contact fingers formed on a lower surface of the package. External electrical connection with other electronic components on a host printed circuit board (PCB) is accomplished by bringing the contact fingers into pressure contact with complementary electrical pads on the PCB. LGA packages are ideal for flash memory cards in that they have a smaller profile and lower inductance than pin grid array (PGA) and ball grid array (BGA) packages.

Semiconductor die are typically batch processed on a panel and then singulated into individual packages upon completion of the fabrication process. Several methods are known for singulating the semiconductor packages including, for example, sawing, water jet cutting, laser cutting, water guided laser cutting, dry media cutting and diamond coated wire cutting.

While laser cutting is an efficient and economical method of singulating semiconductor packages from the panel, laser singulation has certain drawbacks. First, the large amount of heat produced by the laser to cut through the molding compound causes an uncontrolled burning/melting of the various materials in the semiconductor package along the cut lines. For example, the laser cuts through the epoxy of the molding compound, the dielectric material of the substrate and the metal conductive layers on the substrate. These materials may melt and burn differently from each other when cut by the laser. The result of the cuts therefore are rough, non-uniform edges along the cut lines.

Additionally, while steps are taken to minimize moisture within the package during fabrication, it is possible that some moisture or other gasses remain between layers within a package after the molding compound is applied, for example between the substrate and the molding compound. During the laser cut, this trapped moisture/gas heats up rapidly and expands, resulting in pressure build-up between the layers of the package. This pressure build-up may be sufficient to separate package layers. Moreover, during laser singulation, the laser burns and vaporizes the molding compound at the kerf (i.e., cut width). These vapors may adhere to and contaminate the cut edges and/or other surface of the packages.

### SUMMARY OF THE INVENTION

Embodiments of the present invention relate in general to a method of laser singulation of semiconductor packages from a panel. Singulation occurs while the panel is at least partially submerged within a liquid bath filled with water or other liquid capable of rapidly carrying away heat generated by the laser during singulation. The liquid bath may include a fixture for supporting the panel within a fixed, repeatable and registered position.

In embodiments, the fixture supports the panel so that the panel is immersed in the liquid with the bottom surface of the panel being below the surface of the liquid, and the top surface of the panel being approximately even with the upper surface of liquid. It is understood that the upper surface of the panel may be above or below the surface of the liquid in alternative embodiments.

The panel may be cut by a laser to singulate the panel into a plurality of semiconductor packages. The cut may form rectangular, square, irregular-shaped and/or curvilinear-shaped semiconductor packages in embodiments of the invention. During the cut, the liquid may cover the upper surface of the panel to further facilitate cooling of the semiconductor package. After cutting, the singulated semiconductor packages may be removed from the liquid bath.

Immersing the panel within liquid during laser singulation provides several advantages. First, while the laser burns and/or vaporizes the material at the kerf, the edges of the package adjacent the kerf are rapidly cooled and uneven burning/vaporization of the materials at the edges of the package is largely or entirely avoided. Second, moisture and/or other gasses trapped between the layers during the fabrication process are largely prevented from expanding, and the possibility of layers separating under the pressure of the expanding moisture/gasses is minimized. Third, the liquid against the surfaces of the semiconductor package largely prevents the material vaporized by the laser from redepositing on the package, thus greatly reducing contamination due to such vapors.

### BRIEF DESCRIPTION OF THE DRAWINGS

FIG. 1 is a flowchart of the method of fabricating a flash memory card according to embodiments of the present invention.

FIG. 2 is a flowchart of the method of singulating a panel into semiconductor packages according to embodiments of the present invention.

FIG. 3 is a top view of a portion of a panel of integrated circuits during the fabrication process according to the present invention.

FIG. 4 is a cross-sectional view through line 4-4 in FIG. 3.

FIG. 5 is a top view of a panel of molded integrated circuits according to embodiments of the present invention prior to being cut into individual integrated circuit packages.

FIGS. 6 and 7 are perspective and top views, respectively of a liquid bath in which the singulation process may be performed according to embodiments of the present invention.

FIG. 8 is a side view of an integrated circuit panel and liquid bath in which the singulation process may be performed according to embodiments of the present invention.

FIG. 9 is a side view of an integrated circuit panel within a liquid bath in which the singulation process may be performed according to embodiments of the present invention.

FIG. 10 is a top view of a liquid bath in which the singulation process may be performed according to an alternative embodiment of the present invention.

FIG. 11 is a side view of an integrated circuit panel and liquid bath in which the singulation process may be performed according to an alternative embodiment of the present invention.

FIG. 12 is a side view of an integrated circuit panel within a liquid bath in which the singulation process may be performed according to an alternative embodiment of the present invention.

FIG. 13 is a perspective view of a sample flash memory card formed according to embodiments of the present invention.

### DETAILED DESCRIPTION

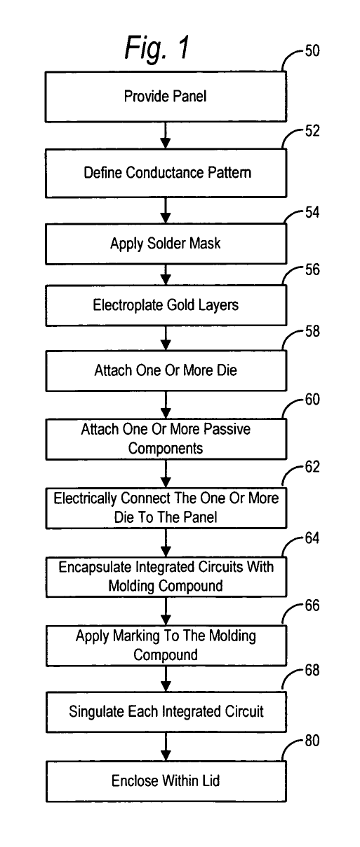

Embodiments of the invention will now be described with reference to FIGS. 1 through 13 which relate to a method of laser singulation of semiconductor packages from a panel while the panel is at least partially submerged within a liquid. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

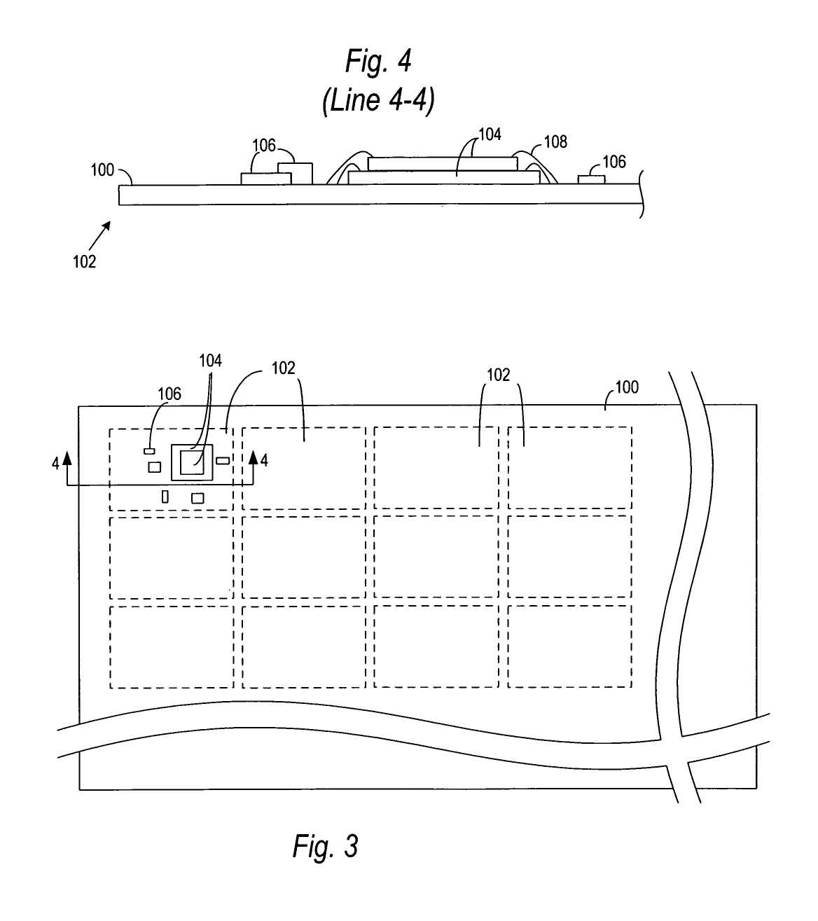

In general, semiconductor packages according to the present invention are formed in a process described with respect to FIG. 1. The fabrication process begins in step 50 with a panel 100, shown partially for example in FIGS. 3 and 4. The type of panel 100 used in the present invention may for example be a leadframe, printed circuit board (“PCB”), a tape used in tape automated bonding (“TAB”) processes, or other known substrates on which integrated circuits may be assembled and encapsulated.

In embodiments where panel 100 is a PCB, the substrate may be formed of a core, having a top conductive layer formed on a top surface of the core, and a bottom conductive layer formed on the bottom surface of the core. The core may be formed of various dielectric materials such as for example, polyimide laminates, epoxy resins including FR4 and FR5, bismaleimide triazine (BT), and the like. The conductive layers may be formed of copper or copper alloys, plated copper or plated copper alloys, Alloy 42 (42 Fe/58 Ni), copper plated steel, or other metals and materials known for use on substrates.

The metal layers of panel 100 may be etched with a conductance pattern in a known process for communicating signals between one or more semiconductor die and an external device (step 52). Once patterned, the substrate may be laminated with a solder mask in a step 54. In embodiments where substrate 100 is used for example as an LGA package, one or more gold layers may be formed on portions of the bottom conductive layer in step 56 to define contact fingers on the bottom surface of the semiconductor package as is known in the art for communication with external devices. The one or more gold layers may be applied in a known electroplating process. It is understood that the semiconductor package according to the present invention need not be an LGA package, and may be a variety of other packages in alternative embodiments including for example BGA packages.

A plurality of discrete integrated circuits 102 may be formed on panel 100 in a batch process to achieve economies of scale. The fabrication of integrated circuits 102 on panel 100 may include the steps 58 and 60 of mounting one or more semiconductor die 104 and passive components 106 on panel 100 for each integrated circuit 102.

The one or more semiconductor die 104 may be mounted in step 58 in a known adhesive or eutectic die bond process, using a known die-attach compound. The number and type of semiconductor die 104 are not critical to the present invention and may vary greatly. In one embodiment, the one or more die 104 may include a flash memory array (e.g., NOR, NAND or other), S-RAM or DDT, and/or a controller chip such as an ASIC. Other semiconductor die are contemplated. The one or more die 114 may be electrically connected to panel 100 by wire bonds 108 in step 62 in a known wire-bond process. The die may be stacked in an SiP arrangement, mounted side-by-side in an MCM arrangement, or affixed in another packaging configuration.

Although not specifically called out on the flowchart of FIG. 1, various visual and automated inspections may be made during the above-described fabrication of the plurality of integrated circuits 102 on panel 100.

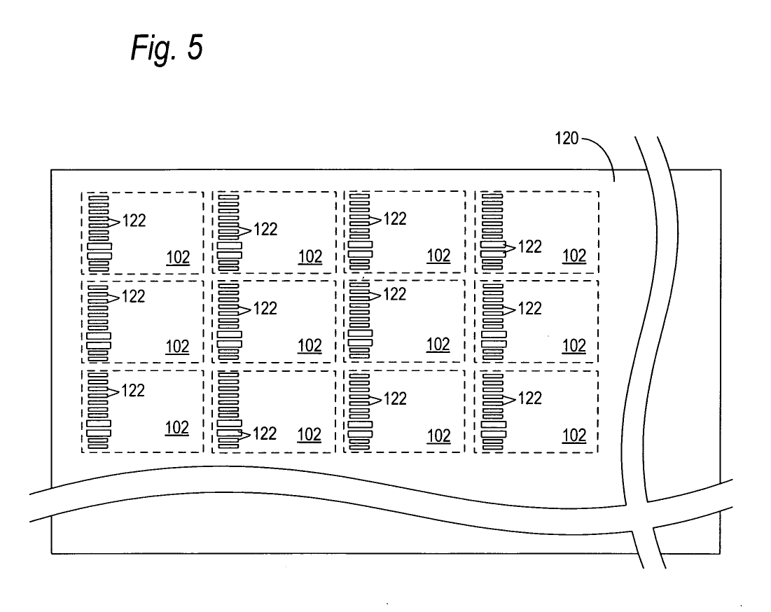

Once the plurality of integrated circuits 102 have been formed on panel 100, each of the integrated circuits 102 may be encapsulated with a molding compound 120 in step 64 and as shown in FIG. 5. Molding compound 120 may be an epoxy such as for example available from Sumitomo Corp. and Nitto Denko Corp., both having headquarters in Japan. Other molding compounds from other manufacturers are contemplated. The molding compound may be applied according to various processes, including by transfer molding or injection molding techniques, to encapsulate each of the integrated circuits 102. As shown in FIG. 5, contact fingers 122 may be left exposed.

Although shown with a generic rectangular shape in FIG. 5, the molded integrated circuits may have irregular and/or curvilinear shapes in embodiments. A method for forming irregular shaped semiconductor packages is disclosed for example in U.S. patent application Ser. No. 11/265,337, entitled “Method of Manufacturing Flash Memory Cards,” which application is assigned to the owner of the present application and which application is incorporated by reference herein in its entirety.

After molding step 64, a marking can be applied to the molding compound 120 in step 66. The marking may for example be a logo or other information printed on the surface of the molding compound 120 for each integrated circuit 102. The marking may for example indicate manufacturer and/or type of device. Marking step 66 may be omitted in alternative embodiments of the present invention.

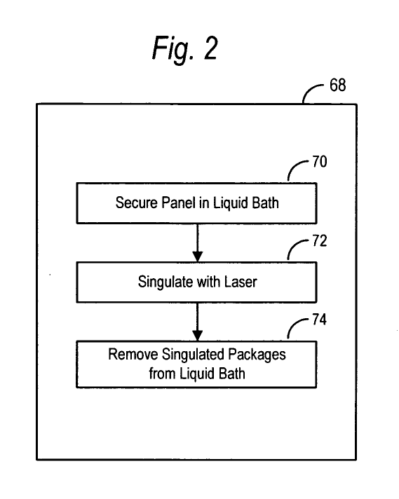

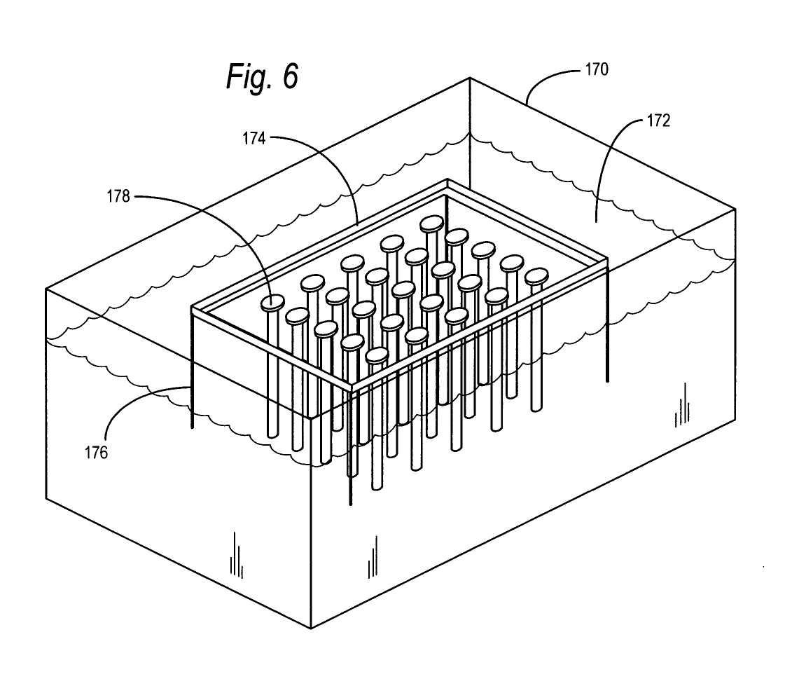

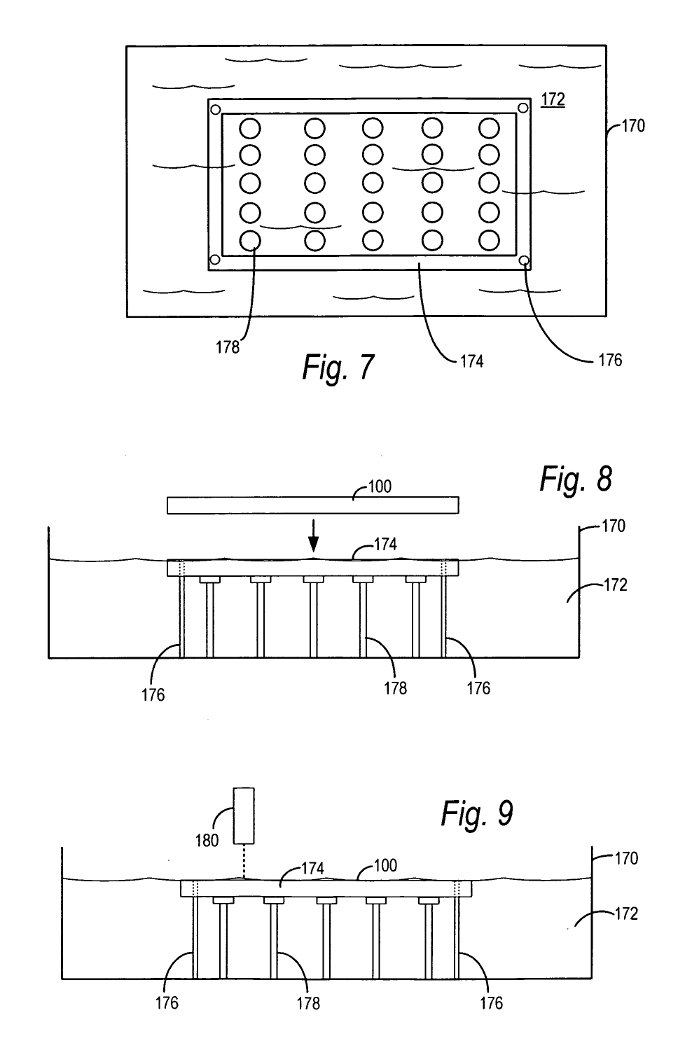

Each of the integrated circuits 102 may next be singulated in step 68. Singulation step 68 involves cutting integrated circuits 102 on panel 100 into a plurality of individual semiconductor packages. The singulation step 58 is explained in greater detail with respect to the flowchart of FIG. 2, the perspective view of FIG. 6, the top view of FIG. 7 and the side views of FIGS. 8-9. The panel 100 may be at least partially immersed in a liquid bath 170 in a step 70. Bath 170 may include a liquid 172 for rapidly cooling the edges of the semiconductor packages after laser singulation as explained hereinafter. The liquid 172 may be water, but may be a variety of other liquids in alternative embodiments. Where liquid 172 is water, the temperature of the water may be between room temperature and 0° C. It is understood that the liquid may be warmer than room temperature in embodiments, and may be cooler than 0° C. in embodiments where the liquid 172 used has a freezing point lower than 0°C.

In embodiments, the liquid 172 may be a solution of more than one liquid. Moreover, solid objects such as ice or other objects may be included within bath 170 to maintain the liquid at a desired temperature. Furthermore, liquid may be added to and/or taken out of bath 170 to maintain the liquid within bath 170 at a desired temperature.

The bath 170 may include a fixture 174 for positioning the panel 100 within the liquid 172. The fixture may be adapted to support the panel 100 in a fixed, repeatable and registered position within the liquid bath 170. The fixture may be formed of various non-oxidizing materials, such as for example stainless steel, and may be supported within the bath 170 on posts 176 which extend to the bottom of bath 170 (as shown), or connect to the vertical sides of bath 170. While the fixture is shown as having four contiguous sides, it is understood that fixture 174 may have other configurations in alternative embodiments. For example, the fixture may be formed of two opposed rails. Alternatively, the fixture may support the panel only at the corners of the panel.

A plurality of support posts 178 may further be provided for supporting the panel 100 within liquid bath 170, and for supporting the individual semiconductor packages within liquid bath 170 after they are singulated from the panel 100. Each support post 178 may include a stainless steel support extending from the bottom of the bath 170 and a rubber suction cup at its upper end on which the panel 100 is supported. In embodiments, the support posts 178 are aligned so that there is one support post positioned beneath each singulated semiconductor package. Thus, after the packages are singulated from the panel, each package remains supported on the suction cup of its respective support post. It is understood that the number of support posts 178 are by way of example only, and there may be more or less support posts than shown in alternative embodiments. Moreover, it is understood that the panel 100 and the individual semiconductor packages may be supported within the bath 170 by other positioning and support structures in alternative embodiments.

In embodiments, the fixture 174 and support posts 178 support the panel 100 so that the panel is immersed in the liquid 172 with the bottom surface of the panel 100 being below the surface of the liquid, and the top surface of the panel 100 being approximately even with the upper surface of liquid 172. It is understood that the upper surface of the panel 100 may be immersed below the upper surface of the liquid, so long as the distance by which the panel is immersed is not so great that the liquid prevents the laser from making an effective cut through the panel. Similarly, it is understood that the upper surface of the panel 100 may be slightly above the surface of the liquid in embodiments of the invention.

The liquid 172 in bath 170 may be a few inches deep (with the fixture 174 and support posts 178 spaced from the bottom surface of the bath accordingly). There may be more or less liquid 172 than that in alternative embodiments. In a further embodiment, there may only be enough liquid 172 in bath 170 to cover the panel while the panel is supported directly on the bottom surface of the bath 170. In such an embodiment, the support posts 178 may be omitted.

As seen in FIG. 9, the panel may be cut by a laser 180 to singulate the panel 100 into a plurality of semiconductor packages (step 72, FIG. 2). As indicated above, the cut may form rectangular, square, irregular-shaped and/or curvilinear-shaped semiconductor packages in embodiments of the invention. A variety of lasers are known for singulating panel 100, including for example CO₂ lasers, YBO₄ lasers, Argon lasers, etc. Such lasers are manufactured for example by Rofin-Sinar Technologies of Hamburg, Germany. During the cut, the liquid 172 may cover the upper surface of the panel 100 due to capillary action, turbulence in the liquid and/or other factors.

After cutting, the singulated semiconductor packages may be removed from the liquid bath 170 in step 74. In an embodiment, a matrix handler of known construction having suction cups may be used to retrieve each singulated package from the bath 170. The suction cups may be provided on the matrix handler so as to align with each of the respective singulated packages. Thus, the matrix handler may retrieve each of the singulated packages from bath 170 in a single retrieving process. It is understood that other mechanisms may be used to retrieve the singulated packages in alternative embodiments.

Immersing the panel 100 within liquid 172 during laser singulation provides several advantages. First, upon cutting through the panel, the liquid 172 rapidly draws heat away from the cut edge. Thus, while the material at the kerf is burned away and/or vaporized, the layers of the package (i.e., the epoxy molding compound, the dielectric substrate and the metal conductive layers) cool down together and relatively quickly. Thus, the uneven melting/burning of the respective materials of the package found in conventional laser singulation is largely or entirely prevented and the cut edge is smooth and even. Second, as heat is drawn away by the liquid 172 so quickly, moisture and/or other gasses trapped between the layers during the fabrication process are largely prevented from expanding, and the possibility of layers separating under the pressure of the expanding moisture/gasses is minimized. Third, the liquid against the surfaces of the semiconductor package largely prevents the material vaporized by the laser from redepositing on the package, thus greatly reducing contamination due to such vapors. Fourth, it is known that laser cutting offer significant advantages over other cutting methods as far as yield rates. For example, singulating semiconductor packages with non-linear cuts using water jet cutting or routing yields about 500 to 1000 units per hour (UPH). Singulating semiconductor packages with a laser as described above yields about 2500 to 4000 UPH.

While there are advantages to singulating a panel at least partially immersed in liquid bath 170 using a laser, it is understood that the panel may be singulated into semiconductor packages while immersed at least partially within bath 170 using other cutting methods.

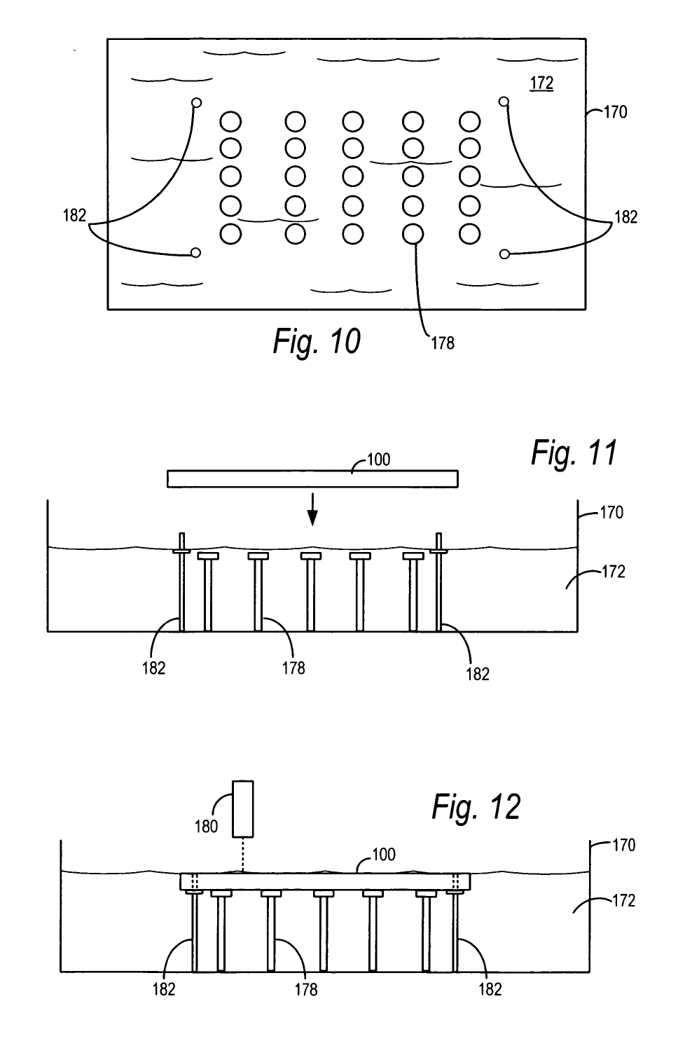

It is understood that a variety of other fixtures and structures may be used to position the panel 100 within the liquid bath 100 for singulation. The top view of FIG. 10 and the side views of FIGS. 11 and 12 show one such alternative. In FIGS. 10 through 12, posts 182 include ends capable of mating within registration holes conventionally formed in panel 100 to fix the panel in a repeatable and registered position for singulation. The posts 182 may position the panel 100 at or near the surface of the liquid 172 as described above. The embodiment of FIGS. 10 through 12 may include support posts 178 as described above.

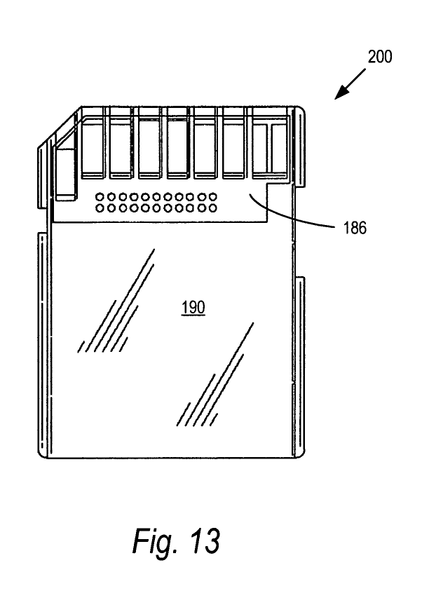

Referring again to the flowchart of FIG. 1 and the bottom view of FIG. 13, a semiconductor package 186 formed as described above may further be enclosed within an external lid 190 in step 80 to form a finished flash memory card 200. Such a lid 190 would provide an external covering for the semiconductor package and establish external product features (for example any notches, chamfers, etc. to aid in proper insertion of the card 200 in a host device). Lid 190 may be applied on one or two sides of the semiconductor package by various processes, for example by over-molding. In such a process, a semiconductor package may be put into an injection molding press and positioned in a fixed and registered position (such as for example by guide pins). Molten plastic or the like may then flow into the mold around the semiconductor package.

The memory card 200 may be formed according to any of a variety of standard card configurations, including for example a Pico card, xD card, an MMC card, an RS-MMC card, an SD Card, a Compact Flash, a Smart Media Card, a Mini SD Card, a Transflash memory card or a Memory Stick. Other devices are contemplated.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method forming a semiconductor package from a panel, comprising the steps of:
(a) immersing the panel at least partially in a liquid bath; and
(b) singulating the semiconductor package from the panel while the panel is at least partially immersed in the liquid bath.

2. A method of forming a semiconductor package as recited in claim 1, wherein said step (b) of singulating the semiconductor package from the panel while the panel is at least partially immersed in the liquid bath comprises the step of cutting the panel with a laser.

3. A method of forming a semiconductor package as recited in claim 1, wherein said step (a) of immersing the panel at least partially in a liquid bath comprising the step of immersing the panel so that an upper surface of the panel is approximately at an upper surface the liquid in the liquid bath.

4. A method of forming a semiconductor package as recited in claim 1, wherein said step (a) of immersing the panel at least partially in a liquid bath comprising the step of immersing the panel so that an upper surface of the panel is beneath an upper surface the liquid in the liquid bath.

5. A method of forming a semiconductor package as recited in claim 1, wherein said step (a) of immersing the panel at least partially in a liquid bath comprising the step of immersing the panel in water.

6. A method of forming a semiconductor package as recited in claim 1, wherein said step (a) of immersing the panel at least partially in a liquid bath comprising the step of positioning the panel in a fixture for registering the panel in a desired position.

7. A method of forming a semiconductor package as recited in claim 1, wherein said step (a) of immersing the panel at least partially in a liquid bath comprising the step of supporting the panel on one or more support posts.

8. A method of forming a semiconductor package as recited in claim 7, wherein said step of supporting the panel on one or more support posts comprises the step of supporting the panel on suction cups on the support posts.

9. A method of forming a semiconductor package as recited in claim 1, wherein said step (b) of singulating the semiconductor package from the panel while the panel is at least partially immersed in the liquid bath comprises the step of cutting semiconductor package with straight edges.

10. A method of forming a semiconductor package as recited in claim 1, wherein said step (b) of singulating the semiconductor package from the panel while the panel is at least partially immersed in the liquid bath comprises the step of cutting semiconductor package with irregular shaped and/or curvilinear edges.

11. A method of forming a semiconductor package as recited in claim 1, further comprising the step (c) of supporting the panel a fixed position within the liquid bath.

12. A method of forming a semiconductor package as recited in claim 11, wherein said step (c) of supporting the panel a fixed position within the liquid bath comprising the step of supporting the panel on four contiguous rails.

13. A method of forming a semiconductor package as recited in claim 11, wherein said step (c) of supporting the panel a fixed position within the liquid bath comprising the step of supporting the panel at corners of the panel.

14. A method of forming a semiconductor package as recited in claim 11, wherein said step (c) of supporting the panel a fixed position within the liquid bath comprising the step of supporting the panel on posts received within registration holes in the panel.

15. A method of forming a method forming a semiconductor package from a panel, comprising the steps of:
(a) forming an integrated circuit on the panel;
(b) encapsulating the integrated circuit and at least one surface of the panel;
(c) immersing the panel at least partially in a liquid bath; and
(d) singulating the semiconductor package from the panel while the panel is at least partially immersed in the liquid bath.

16. A method of forming a semiconductor package as recited in claim 15, further comprising the step of encasing the semiconductor package in at least one lid.

17. A method of forming a semiconductor package as recited in claim 15, wherein said step (d) of singulating the semiconductor package from the panel while the panel is at least partially immersed in the liquid bath comprises the step of cutting the panel with a laser.

18. A method of forming a semiconductor package as recited in claim 15, wherein said step (c) of immersing the panel at least partially in a liquid bath comprising the step of immersing the panel so that an upper surface of the panel is approximately at an upper surface the liquid in the liquid bath.

19. A method of forming a semiconductor package as recited in claim 15, wherein said step (c) of immersing the panel at least partially in a liquid bath comprising the step of immersing the panel so that an upper surface of the panel is beneath an upper surface the liquid in the liquid bath.

20. A method of forming a semiconductor package as recited in claim 15, wherein said step (c) of immersing the panel at least partially in a liquid bath comprising the step of immersing the panel in water.

21. A method of forming a semiconductor package as recited in claim 20, further comprising the step of adding ice to the liquid bath.

22. A method of forming a semiconductor package as recited in claim 15, further comprising the step of adding liquid to the liquid bath to maintain a temperature of the liquid bath.

23. A method of forming a semiconductor package as recited in claim 15, further comprising the step of removing liquid from the liquid bath to maintain a temperature of the liquid bath.

24. A method of forming a semiconductor package as recited in claim 15, further comprising the step of supporting the panel a fixed position within the liquid bath.

25. A method forming a flash memory card, comprising the steps of:
(a) forming an integrated circuit on a panel;
(b) encapsulating the integrated circuit and at least one surface of the panel;
(c) immersing the panel at least partially in a liquid bath;
(d) singulating the panel with a laser into at least one semiconductor package while the panel is at least partially immersed in the liquid bath; and
(e) encasing the semiconductor package in at least one lid

26. A method of forming a flash memory as recited in claim 25, wherein said step (a) of forming an integrated circuit on a panel comprises the step of forming at least one of a flash memory array, S-RAM, DDT, and a controller circuit.

27. A method of forming a flash memory as recited in claim 25, wherein the flash memory card is one of a Pico card, xD card, an MMC card, an RS-MMC card, an SD Card, a Compact Flash, a Smart Media Card, a Mini SD Card, a Transflash memory card or a Memory Stick.

28. A method of forming a flash memory as recited in claim 25, wherein said step (c) of immersing the panel at least partially in a liquid bath comprising the step of immersing the panel so that an upper surface of the panel is approximately at an upper surface the liquid in the liquid bath.

29. A method of forming a flash memory as recited in claim 25, wherein said step (c) of immersing the panel at least partially in a liquid bath comprising the step of immersing the panel so that an upper surface of the panel is beneath an upper surface the liquid in the liquid bath.

30. A method of forming a flash memory as recited in claim 25, wherein said step (c) of immersing the panel at least partially in a liquid bath comprising the step of immersing the panel in water.

31. A method of forming a flash memory as recited in claim 25, further comprising the step of supporting the panel a fixed position within the liquid bath.

32. A method of forming a semiconductor package as recited in claim 31, wherein said step of supporting the panel a fixed position within the liquid bath comprising the step of supporting the panel on four contiguous rails.

33. A method of forming a semiconductor package as recited in claim 31, wherein said step of supporting the panel a fixed position within the liquid bath comprising the step of supporting the panel at corners of the panel.

34. A method of forming a semiconductor package as recited in claim 31, wherein said step of supporting the panel a fixed position within the liquid bath comprising the step of supporting the panel on posts received within registration holes in the panel.
